(19) United States
(12) Patent Application Publication
(10) Pub. No.: US 2026/0247673 A1
(43) Pub. Date: Aug. 20, 2026

(54) SYSTEMS AND METHODS FOR TUNING POROUS BANDGAPS TO REDUCE THERMAL DONOR EFFECTS

(71) Applicant: IQE plc, St. Mellons, Cardiff (GB)

(72) Inventor: Richard HAMMOND, St. Mellons, Cardiff (GB)

(21) Appl. No.: 19/136,388

(22) PCT Filed: Dec. 6, 2023
(86) PCT No.: PCT/EP2023/084579

§ 371 Date: Jun. 6, 2025

(30) Foreign Application Priority Data
Dec. 12, 2022 (GB) 2218656.3

(51) Int. Cl. H10D 62/60; H10D 62/53; H10W 10/10

(52) U.S. Cl. CPC H10D 62/60; H10D 62/53; H10W 10/181

(57) ABSTRACT

A layered structure includes a substrate and a porous layer over the substrate. The substrate has a first resistivity and a first bandgap (E_{g1}). The porous layer has a second resistivity higher than the substrate and a second bandgap (E_{g2}) higher than the first bandgap (E_{g1}). The bandgap ratio (E_{g2}/E_{g1}) of the second bandgap (E_{g2}) to the first bandgap (E_{g1}) is at least 1.3 at an operating temperature of at least 100° C. Advantageously the bandgap ratio (E_{g2}/E_{g1}) can decrease thermal donor effects, maintain high resistivity of the porous layer, decrease harmonic losses at device operating temperatures, and increase device performance.

### BACKGROUND

### Field

The present disclosure relates to porous apparatuses, systems, and methods, for example, porous apparatuses, systems, and methods having porous bandgaps to decrease thermal donor effects, maintain high resistivity, and decrease harmonic losses.

### Background

Semiconductor-on-insulator (SOI) structures are commonly employed to realize radio frequency (RF) designs where low signal leakage is required. These SOI structures use a buried oxide (BOX) under a top device layer in which RF circuit components, such as transistors and/or passive components, can be fabricated. A handle wafer functioning as a substrate under the BOX can result in signal leakage due to RF fringing fields penetrating into the substrate.

Current incumbent RF-SOI technology utilizes a trap-rich SOI to reduce carrier accumulation due to RF fringing fields and improve harmonic losses. A trap-rich layer (e.g., polysilicon) is formed between the handle wafer and the BOX to minimize parasitic surface conduction effects that can adversely affect RF devices in the top device layer. In addition, to further improve substrate harmonic losses, high-resistivity handle wafers (e.g., greater than 3,000 Ω·cm) are used to reduce the amount of free charge carriers. However, this approach requires costly and/or specialized fabrication techniques.

Porous semiconductors are an alternative to SOI substrates. Porous semiconductors can achieve high-resistivity properties on a standard CMOS silicon wafer, rather than a high-resistivity SOI wafer. Porosification can form a porous region with a particular thickness, porosity, and bandgap in a layer or substrate. For example, electrochemically etching a standard low-resistivity (e.g., 1 Ω·cm) silicon wafer can form a thick (e.g., greater than 2 microns) porous silicon surface layer having a bandgap in a range of about 1.7 eV to about 2.2 eV. The porous etch can deplete free charge carriers within the silicon and increase a resistivity of the porous silicon layer by several orders of magnitude (e.g., from 1 Ω·cm to greater than 5,000 Ω·cm). The high-resistivity and low relative permittivity (e.g., about 2.2) of porous silicon can suppress harmonic losses by several orders of magnitude more than trap-rich SOI.

Further, porous silicon provides an epitaxy platform to regrow a defect-free, single crystal silicon epilayer. Epitaxy refers to crystal growth or material deposition in which new crystalline layers are formed with one or more well-defined orientations. Epitaxy can be used to grow high quality, single crystal semiconductors atop the porous layer. For example, such an epilayer can be used as a device layer for RF circuit components (e.g., an RF CMOS switch).

However, at device operating temperatures, heat can be transferred into the high-resistivity SOI wafer, thereby creating thermally generated charge carriers that cause thermal donor effects, for example, resulting in decreased resistivity and increased harmonic losses. The amount of thermally generated charge carriers, which is proportional to the intrinsic carrier concentration of a semiconductor, is exponentially dependent upon the negative of the bandgap of the material. Thus, the higher the bandgap (positive value) of the material, the lower the number of thermally generated carriers at a particular operating temperature (e.g., 100° C.), and, conversely, the lower the bandgap (positive value) of the material, the higher the number of thermally generated charge carriers at a particular operating temperature (e.g., 100° C.).

### SUMMARY

Accordingly, there is a need to utilize a porous layer having a bandgap higher than a bandgap of the substrate on which the porous layer is formed to simultaneously decrease thermal donor effects (e.g., decreased resistivity, harmonic losses, etc.), maintain high resistivity of the porous layer (e.g., greater than 5,000 Ω·cm), decrease harmonic losses at device operating temperatures (e.g., at least 100° C.), and increase manufacturing efficiency and yield.

In some aspects, a layered structure can include a substrate and a porous layer over the substrate. In some aspects, the substrate can have a first resistivity and a first bandgap. In some aspects, the porous layer can have a second resistivity higher than the substrate and a second bandgap higher than the first bandgap. In some aspects, a bandgap ratio of the second bandgap to the first bandgap can be at least 1.3. In some aspects, a bandgap ratio of the second bandgap to the first bandgap can be at least 1.6. For example, the first bandgap can be about 1.1 eV (e.g., bulk silicon) and the second bandgap can be about 1.78 eV (e.g., porous silicon), having a bandgap ratio of about 1.62. For example, the first bandgap can be about 1.42 eV (e.g., bulk gallium arsenide) and the second bandgap can be about 2.3 eV (e.g., porous gallium arsenide), having a bandgap ratio of about 1.62. Advantageously the bandgap ratio can decrease thermal donor effects, maintain high resistivity of the porous layer, decrease harmonic losses at device operating temperatures (e.g., at least 100° C.), and increase device performance.

In some aspects, the bandgap ratio can be at least 1.9. For example, the first bandgap can be about 1.1 eV (e.g., bulk silicon) and the second bandgap can be about 2.1 eV (e.g., porous silicon), having a bandgap ratio of about 1.91. Advantageously the bandgap ratio can decrease thermal donor effects, maintain high resistivity of the porous layer, decrease harmonic losses at device operating temperatures (e.g., at least 100° C.), and increase device performance.

In some aspects, the bandgap ratio can be at least 2.5. For example, the first bandgap can be about 0.67 eV (e.g., bulk germanium) and the second bandgap can be about 2.2 eV (e.g., porous germanium), having a bandgap ratio of about 3.28. Advantageously the bandgap ratio can decrease thermal donor effects, maintain high resistivity of the porous layer, decrease harmonic losses at device operating temperatures (e.g., at least 100° C.), and increase device performance.

In some aspects, the bandgap ratio can be at least 4. For example, the first bandgap can be about 0.67 eV (e.g., bulk germanium) and the second bandgap can be about 2.8 eV (e.g., porous germanium), having a bandgap ratio of about 4.18. Advantageously the bandgap ratio can decrease thermal donor effects, maintain high resistivity of the porous layer, decrease harmonic losses at device operating temperatures (e.g., at least 100° C.), and increase device performance.

In some aspects, the porous layer can have a thermal donor carrier concentration of no greater than about 1×10¹³ cm⁻³ at an operating temperature of at least 100° C. For example, porous silicon (e.g., second bandgap of about 1.9 eV) can have a thermal donor carrier concentration of about 2×10¹² cm⁻³ at an operating temperature of about 200° C. Advantageously the decreased thermal donor carrier concentration decreases thermal donor effects, maintain high resistivity of the porous layer, and decrease harmonic losses at device operating temperatures (e.g., at 100° C.).

In some aspects, the porous layer can have a thermal donor carrier concentration of no greater than about 1×10¹² cm⁻³ at an operating temperature of at least 100° C. For example, porous gallium arsenide (e.g., second bandgap of about 1.5 eV) can have a thermal donor carrier concentration of about 2.4×10¹⁰ cm⁻³ at an operating temperature of about 200° C. Advantageously the decreased thermal donor carrier concentration decreases thermal donor effects, maintain high resistivity of the porous layer, and decrease harmonic losses at device operating temperatures (e.g., at 100° C.).

In some aspects, the porous layer can have a thermal donor carrier concentration of no greater than about 1×10¹¹ cm⁻³ at an operating temperature of at least 100° C. For example, porous gallium arsenide (e.g., second bandgap of about 1.8 eV) can have a thermal donor carrier concentration of about 1.8×10¹⁰ cm⁻³ at an operating temperature of about 200° C. Advantageously the decreased thermal donor carrier concentration decreases thermal donor effects, maintain high resistivity of the porous layer, and decrease harmonic losses at device operating temperatures (e.g., at 100° C.).

In some aspects, the porous layer can have a thermal donor carrier concentration of no greater than about 1×10¹⁰ cm⁻³ at an operating temperature of at least 100° C. For example, porous gallium arsenide (e.g., second bandgap of about 2.3 eV) can have a thermal donor carrier concentration of about 1×10¹⁰ cm⁻³ at an operating temperature of about 200° C. Advantageously the decreased thermal donor carrier concentration decreases thermal donor effects, maintain high resistivity of the porous layer, and decrease harmonic losses at device operating temperatures (e.g., at 100° C.).

In some aspects, a thermal donor carrier concentration ratio of a thermal donor carrier concentration of the substrate to a thermal donor carrier concentration of the porous layer can be at least 50. For example, the substrate thermal donor carrier concentration can be about 1×10¹⁴ cm⁻³ (e.g., bulk silicon at about 200° C.) and the porous layer thermal donor carrier concentration can be about 2×10¹² cm⁻³ (e.g., porous silicon at about 200° C.), having a thermal donor carrier concentration ratio of about 50. Advantageously the thermal donor carrier concentration ratio can decrease thermal donor effects, maintain high resistivity of the porous layer, and decrease harmonic losses at device operating temperatures (e.g., at least 100° C.).

In some aspects, the thermal donor carrier concentration ratio can be at least 100. For example, the substrate thermal donor carrier concentration can be about 1×10¹⁶ cm⁻³ (e.g., bulk germanium at about 200° C.) and the porous layer thermal donor carrier concentration can be about 9.1×10¹³ cm⁻³ (e.g., porous germanium at about 200° C.), having a thermal donor carrier concentration ratio of about 110. Advantageously the thermal donor carrier concentration ratio can decrease thermal donor effects, maintain high resistivity of the porous layer, and decrease harmonic losses at device operating temperatures (e.g., at least 100° C.).

In some aspects, the thermal donor carrier concentration ratio can be at least 200. For example, the substrate thermal donor carrier concentration can be about 1×10¹⁶ cm⁻³ (e.g., bulk germanium at about 200° C.) and the porous layer thermal donor carrier concentration can be about 4.8×10¹³ cm⁻³ (e.g., porous germanium at about 200° C.), having a thermal donor carrier concentration ratio of about 208. Advantageously the thermal donor carrier concentration ratio can decrease thermal donor effects, maintain high resistivity of the porous layer, and decrease harmonic losses at device operating temperatures (e.g., at least 100° C.).

In some aspects, the porous layer can include a porous Group IV semiconductor, a porous Group III-V semiconductor, or a combination thereof. In some aspects, the porous layer can include porous silicon (Si), porous germanium (Ge), porous gallium arsenide (GaAs), porous indium nitride (InN), porous indium phosphide (InP), porous silicon carbide (SiC), porous gallium nitride (GaN), or porous aluminum nitride (AlN). Advantageously the porous layer can include a variety of materials each providing a bandgap ratio that can decrease thermal donor effects, maintain high resistivity of the porous layer, and decrease harmonic losses at device operating temperatures (e.g., at least 100° C.).

In some aspects, the porous layer is elementally identical to the substrate. For example, the substrate can be bulk silicon and the porous layer can be porous silicon. Advantageously elementally identical materials can increase manufacturing efficiency and yield.

In some aspects, the porous layer can be a fully depleted porous layer having no free charge carriers. Advantageously the fully depleted porous layer can have a high second bandgap (e.g., at least 1.9 eV for porous silicon) thereby decreasing thermal donor effects and maintaining a high second resistivity of the porous layer (e.g., greater than 5,000 Ω·cm).

In some aspects, the first resistivity of the substrate can be between about 0.01 Ω·cm and 10 Ω·cm. In some aspects, the second resistivity of the porous layer can be at least 5,000 Ω·cm. In some aspects, the porous layer can have a thickness of at least 2 μm. Advantageously the high resistivity and thickness of the porous layer decreases harmonic losses at device operating temperatures (e.g., at least 100° C.)

In some aspects, the second bandgap of the porous layer can be based on a porosity of the porous layer. For example, the second bandgap can be in a range between about 1.7 eV to about 2.2 eV (e.g., for porous silicon) based on a porosity range between about 20% to about 80%, respectively. In some aspects, the second bandgap of the porous layer can be tuned to a specific bandgap value based on the porosity of the porous layer, for example, by adjusting an electrolyte concentration, an electrolyte current density, an electrolyte current fluid velocity, an anodization time, a temperature, a material doping, or a combination thereof during porosification of the substrate to form the porous layer. Advantageously the second bandgap of the porous layer can be tuned to a specific bandgap value based on the porosity of the porous layer, for example, for a particular application or device structure.

In some aspects, the layered structure can further include a semiconductor device in or on the porous layer. In some aspects, the semiconductor device can include a passive device (e.g., an inductor, a filter, etc.). In some aspects, the semiconductor device can include an RF device (e.g., an RF inductor, an RF filter, etc.). Advantageously the bandgap ratio can decrease harmonic losses in the semiconductor device at device operating temperatures (e.g., at least 100° C.).

In some aspects, the layered structure can further include an epitaxial layer grown directly over the porous layer. In some aspects, the layered structure can further include a semiconductor device in the epitaxial layer. In some aspects, the bandgap ratio can be configured to decrease a thermal donor carrier concentration of the porous layer thereby decreasing harmonic losses in the semiconductor device. Advantageously the bandgap ratio can decrease harmonic losses in the semiconductor device at device operating temperatures (e.g., at least 200° C.).

In some aspects, a method can include forming a porous layer over a substrate. In some aspects, the porous layer can have a second bandgap higher than a first bandgap of the substrate. In some aspects, a bandgap ratio of the second bandgap to the first bandgap can be at least 1.3. In some aspects, a bandgap ratio of the second bandgap to the first bandgap can be at least 1.6. Advantageously the bandgap ratio can decrease thermal donor effects, maintain high resistivity of the porous layer, decrease harmonic losses at device operating temperatures (e.g., at least 100° C.), and increase device performance.

In some aspects, the porous layer can have a thermal donor carrier concentration of no greater than about 1×10¹³ cm⁻³ at an operating temperature of at least 200° C. Advantageously the decreased thermal donor carrier concentration decreases thermal donor effects (e.g., decreased resistivity, harmonic losses, etc.), maintain high resistivity of the porous layer, and decrease harmonic losses at device operating temperatures (e.g., at 100° C.).

In some aspects, a thermal donor carrier concentration ratio of a thermal donor carrier concentration of the substrate to a thermal donor carrier concentration of the porous layer can be at least 50. Advantageously the thermal donor carrier concentration ratio can decrease thermal donor effects, maintain high resistivity of the porous layer, and decrease harmonic losses at device operating temperatures (e.g., at least 100° C.).

In some aspects, the porous layer can include porous Si, porous Ge, porous GaAs, porous InN, porous InP, porous SiC, porous GaN, or porous AlN. Advantageously the porous layer can include a variety of materials each providing a bandgap ratio that can decrease thermal donor effects, maintain high resistivity of the porous layer, and decrease harmonic losses at device operating temperatures (e.g., at least 100° C.).

In some aspects, the method can further include annealing the porous layer. In some aspects, the annealing can occur in an oxidation environment (e.g., oxygen, air, water vapor, etc.). Advantageously annealing can decrease stress in the porous layer and increase thermal stability (e.g., crystallinity) of the porous layer, for example, prior to growth of an epitaxial layer over the porous layer.

In some aspects, forming the porous layer can include porosifying an upper portion of the substrate. Advantageously porosifying the substrate can reduce cost and improve manufacturing efficiency of the layered structure.

In some aspects, the second bandgap of the porous layer can be based on an electrolyte concentration, an electrolyte current density, an electrolyte current fluid velocity, an anodization time, a temperature, a material doping, or a combination thereof during porosifying. Advantageously the second bandgap of the porous layer can be tuned to a specific bandgap value based on adjustable parameters during porosification, for example, for a particular application or device structure.

In some aspects, the method can further include forming a passive or semiconductor device in the porous layer. Advantageously the bandgap ratio can decrease harmonic losses in the semiconductor device at device operating temperatures (e.g., at least 100° C.).

In some aspects, the method can further include growing an epitaxial layer directly over the porous layer. In some aspects, the method can further include polishing or etching a frontside of the porous layer prior to growing the epitaxial layer. In some aspects, the method can further include forming a semiconductor device in the epitaxial layer. Advantageously the bandgap ratio can decrease harmonic losses in the semiconductor device at device operating temperatures (e.g., at least 100° C.).

Implementations of any of the techniques described above can include a system, a method, a process, a device, and/or an apparatus. The details of one or more implementations are set forth in the accompanying drawings and the description below. Other features will be apparent from the description and drawings, and from the claims.

Further features and exemplary aspects of the aspects, as well as the structure and operation of various aspects, are described in detail below with reference to the accompanying drawings. It is noted that the aspects are not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the aspects and, together with the description, further serve to explain the principles of the aspects and to enable a person skilled in the relevant art(s) to make and use the aspects.

FIG. 1 is a schematic cross-sectional illustration of a previously known trap-rich SOI layered structure.

FIG. 2 is a schematic cross-sectional illustration of a porosification system, according to an exemplary aspect.

FIG. 3A is a schematic cross-sectional illustration of a porous layered structure, according to an exemplary aspect.

FIG. 3B is a schematic cross-sectional illustration of a porous layered structure, according to an exemplary aspect.

FIG. 4 is a schematic circuit diagram of a transceiver including an RF switch employing stacked transistors, according to an exemplary aspect.

FIG. 5 is a plot of thermal donor carrier concentration as a function of temperature for various materials, according to an exemplary aspect.

FIG. 6 is a schematic cross-sectional illustration of a porous layered structure having a bandgap ratio (E_{g2}/E_{g1}), according to an exemplary aspect.

FIG. 7 is a schematic cross-sectional illustration of a porous layered structure having a bandgap ratio (E_{g2}/E_{g1}), according to an exemplary aspect.

FIG. 8 is a schematic manufacturing diagram for forming the porous layered structure shown in FIG. 6, according to an exemplary aspect.

FIG. 9 is a schematic manufacturing diagram for forming the porous layered structure shown in FIG. 7, according to an exemplary aspect.

FIG. 10 is a flow diagram for forming the porous layered structures shown in FIGS. 6 and 7, according to an exemplary aspect.

The features and exemplary aspects of the aspects will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more aspects that incorporate the features of this present invention. The disclosed aspect(s) merely exemplify the present invention. The scope of the invention is not limited to the disclosed aspect(s). The present invention is defined by the claims appended hereto.

The aspect(s) described, and references in the specification to “one aspect,” “an aspect,” “an example aspect,” “an exemplary aspect,” etc., indicate that the aspect(s) described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of one skilled in the art to affect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The term “about” or “substantially” or “approximately” as used herein means the value of a given quantity that can vary based on a particular technology. Based on the particular technology, the term “about” or “substantially” or “approximately” can indicate a value of a given quantity that varies within, for example, 0.1-10% of the value (e.g., ±0.1%, ±1%, ±2%, ±5%, or ±10% of the value).

The term “epitaxy” or “epitaxial” as used herein means crystalline growth of material, for example, via high temperature deposition. Epitaxy can be effected in a molecular beam epitaxy (MBE) tool in which layers are grown on a heated substrate in an ultra-high vacuum environment. Elemental sources are heated in furnaces and directed towards the substrate without carrier gases. The elemental constituents react at the substrate surface to create a deposited layer.

Epitaxy can also be performed in a vapor phase epitaxy (VPE) tool, also known as a chemical vapor deposition (CVD) tool. CVD is the formation of stable solids by decomposition of gaseous chemicals using heat, plasma, ultraviolet, or other energy sources. Silicon epitaxy can be produced by CVD using heat as the energy source to decompose gaseous chemicals. For example, silicon and dopant atoms can be brought to a single crystal surface by gaseous transport to form a doped epitaxial layer. The CVD tool can be controlled by reactor design variables and operator variables, each of which can influence the uniformity, productivity, and quality of the epitaxial layer.

Epitaxy can also be performed in a metal-organic vapor phase epitaxy (MOVPE) tool, also known as a metal-organic chemical vapor deposition (MOCVD) tool. Compound metal-organic and hydride sources flow over a heated surface using a carrier gas, for example, hydrogen. Epitaxial deposition in the MOCVD tool occurs at higher pressures than in an MBE tool. The compound constituents are cracked in the gas phase and then reacted at the surface to grow layers of desired composition.

The term “compound semiconductor material” or “Group III-V semiconductor” or “III-V semiconductor” or “III-V material” as used herein means including one or more materials from Group III of the periodic table (e.g., group 13 elements: boron (B), aluminum (Al), gallium (Ga), indium (In), thallium (Tl)) with one or more materials from Group V of the periodic table (e.g., group 15 elements: nitrogen (N), phosphorus (P), arsenic (As), antimony (Sb), bismuth (Bi)). The compounds have a 1:1 combination of Group III and Group V regardless of the number of elements from each group. Subscripts in chemical symbols of compounds refer to the proportion of that element within that group. For example, Al_{0.25}Ga_{0.75}As means the Group III part comprises 25% Al, and thus 75% Ga, while the Group V part comprises 100% As.

The term “Group IV semiconductor” as used herein indicates comprising one or more materials from Group IV of the periodic table (e.g., group 14 elements: carbon (C), silicon (Si), germanium (Ge), tin (Sn), lead (Pb)). An alloy can be formed from one or more Group IV elements. Subscripts in chemical symbols of the alloy refer to the proportion of that element within the alloy. For example, Si_{0.8}Ge_{0.2} means the alloy comprises 80% Si and 20% Ge.

The term “Group II-VI semiconductor” as used herein indicates comprising one or more materials from Group II of the periodic table (e.g., group 12 elements: zinc (Zn), cadmium (Cd), mercury (Hg)) with one or more materials from Group VI of the periodic table (e.g., group 16 elements: oxygen (O), sulfur (S), selenium (Se), tellurium (Te)).

The term “substrate” as used herein means a planar wafer on which subsequent layers may be deposited, formed, or grown. A substrate may be formed of a single element (e.g., Si) or a compound material (e.g., GaAs), and may be doped or undoped. In some aspects, for example, a substrate can include Si, Ge, GaAs, GaN, GaP, GaSb, InN, InP, InSb, AlN, a Group IV semiconductor, a Group III-V semiconductor, a Group II-VI semiconductor, graphene, or silicon carbide (SiC).

A substrate may be on-axis, that is where the growth surface aligns with a crystal plane. For example, a substrate can have <100> crystal orientation. Reference herein to a substrate in a given crystal orientation also encompass a substrate which is miscut by up to about 200 towards another crystallographic direction. For example, a (100) substrate miscut towards the (111) plane.

The term “monolithic” as used herein means a layer or substrate comprising bulk (e.g., single) material throughout. Alternatively, the layer or substrate may be porous for some or all of its thickness.

The term “doping” or “doped” as used herein means that a layer or material contains a small impurity concentration of another element (dopant) which donates (donor) or extracts (acceptor) charge carriers from the parent material and therefore alters the conductivity. Charge carriers may be electrons or holes. A doped material with extra electrons is called n-type while a doped material with extra holes (fewer electrons) is called p-type.

The term “crystalline” as used herein means a material or layer with a single crystal orientation. In epitaxial growth or deposition, subsequent layers with the same or similar lattice constant follow the registry of the previous crystalline layer and therefore grow with the same crystal orientation or crystallinity. As will be understood by a person of ordinary skill in the art, crystal orientation, for example, <100> means the face of cubic crystal structure and encompasses [100], [010], and [001] orientations using the Miller indices. Similarly, for example, <0001> encompasses [0001] and [000-1], except if the material polarity is critical. Also, integer multiples of any one or more of the indices are equivalent to the unitary version of the index. For example, (222) is equivalent to (111).

The term “lattice matched” as used herein means that two crystalline layers have the same, or similar, lattice spacing such that the second layer will tend to grow isomorphically (e.g., same crystalline form) on the first layer, also known as pseudomorphic (e.g., near-lattice-matched).

The term “lattice constant” as used herein means the smallest periodicity of a crystalline lattice along a certain crystal orientation. For example, the unstrained lattice spacing of a crystalline unit cell.

The term “deposition” as used herein means the depositing of a layer on another layer or substrate. Deposition encompasses epitaxy, physical vapor deposition (PVD), electron-beam PVD (EBPVD), sputter deposition, chemical vapor deposition (CVD), plasma-enhanced CVD (PECVD), atomic layer deposition (ALD), powder bed deposition, and/or other known techniques to deposit material in a layer.

The term “lateral” or “in-plane” as used herein means parallel to the surface of the substrate and perpendicular to the growth direction.

The term “vertical” or “out-of-plane” as used herein means perpendicular to the surface of the substrate and in the growth direction.

The term “porosifying” or “porosification” as used herein means forming a porous region with a particular thickness and porosity in a layer or substrate. The porosity of a material is affected by electrolyte concentration, electrolyte current density, electrolyte current fluid velocity, anodization time, temperature, and/or material doping. Porosifying can include electrochemical (EC) etching or photoelectrochemical (PEC) etching to form one or more porous layers in a layer or substrate. For example, an electrolyte current (e.g., hydrofluoric acid (HF) at 100 mA/cm² and 20° C.) can be applied to a layer to form one or more porous layers.

The term “porous region” or “porous layer” as used herein means a layer that includes air or vacuum pores, with the porosity defined as the proportion of the area which is occupied by the pores rather than the bulk (e.g., single) material (e.g., a percentage %). The porosity can vary through the thickness of the layer. For example, the layer may be porous in one or more sublayers. The layer may include an upper portion which is porous and a lower portion that is non-porous. The porosity may be constant or variable within the porous region. Where the porosity is variable, the porosity may be linearly varied through the thickness, or may be varied according to a different function, for example, quadratic, logarithmic, or a step function. Pores in the porous layer can be microporous (e.g., less than 2 nm pore size), mesoporous (e.g., 2 nm to 50 nm pore size), nanoporous (e.g., less than 100 nm pore size), or macroporous (e.g., 50 nm to 1000 nm pore size).

Numerical values, including endpoints of ranges, can be expressed herein as approximations preceded by the term “about,” “substantially,” “approximately,” or the like. In such cases, other aspects include the particular numerical values. Regardless of whether a numerical value is expressed as an approximation, two aspects are included in this disclosure: one expressed as an approximation, and another not expressed as an approximation. It will be further understood that an endpoint of each range is significant both in relation to another endpoint, and independently of another endpoint.

Before describing aspects of the present disclosure in more detail, it is instructive to present exemplary layered structures, porosification systems, and environments in which aspects of the present disclosure may be implemented.

### Exemplary Layered Structures and Porosification Systems

As discussed above, porous semiconductors are an alternative to current incumbent RF-SOI technology that utilize trap-rich SOI substrates. Porosification can form a thick porous region with a particular thickness (e.g., greater than 2 microns) and porosity (e.g., about 20% to 80%) in a layer or substrate, and achieve high-resistivity (e.g., greater than 5,000 Ω·cm) on a standard CMOS wafer (e.g., silicon wafer). The high-resistivity porous layer (e.g., porous silicon) can suppress harmonic losses by several orders of magnitude more than trap-rich SOI. Further, the porous layer provides an epitaxy platform to regrow a defect-free, single crystal epilayer. For example, such an epilayer can be used as a device layer for RF circuit components (e.g., an RF CMOS switch).

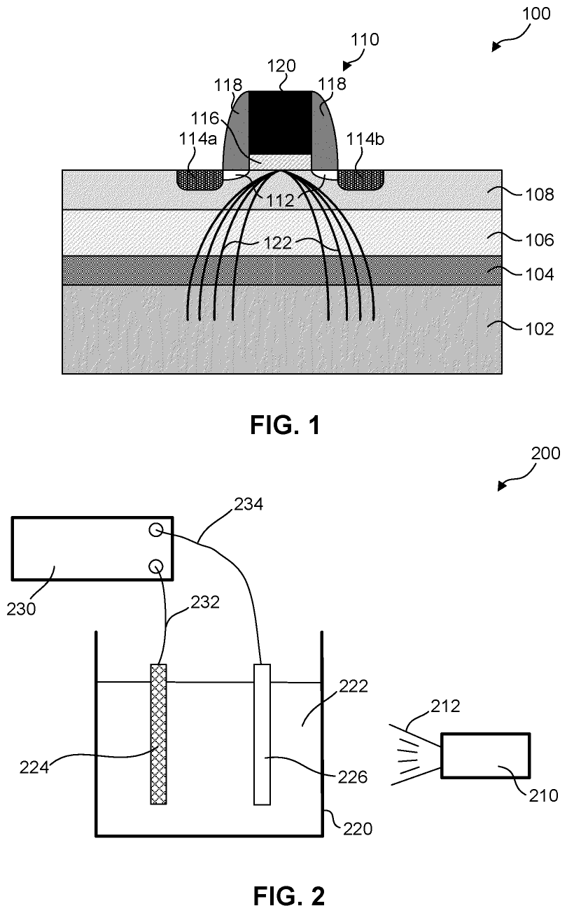

FIG. 1 illustrates trap-rich SOI layered structure 100, according to a previously known configuration. In the example shown in FIG. 1, trap-rich SOI layered structure 100 includes substrate 102 (e.g., silicon), trap-rich layer 104 (e.g., polysilicon), buried oxide (BOX) layer 106 (e.g., silicon dioxide), semiconductor layer 108 (e.g., silicon), and semiconductor device 110 (e.g., MOSFET) in semiconductor layer 108. According to such a configuration, semiconductor device 110 produces RF field lines 122 that penetrate (bleed) through trap-rich layer 104 and BOX layer 106 into substrate 102. This configuration causes significant harmonic losses, crosstalk, and parasitic surface conduction effects.

Semiconductor device 110 can include lightly doped regions 112, source/drain junctions 114a, 114b, gate oxide 116, spacers 118, and gate 120. Lightly doped regions 112 can be implanted with a dopant of a different type (e.g., n-type) than the corresponding semiconductor layer 108 (e.g., p-type). Source/drain junctions 114a, 114b can be implanted with a dopant of the same type as adjacent lightly doped regions 112, but having a higher concentration than lightly doped regions 112. Gate oxide 116 can comprise an electrical insulator, for example, silicon dioxide (SiO₂). Spacers 118 can comprise an electrical insulator, for example, silicon nitride (SiN). Gate 120 can comprise an electrical conductor, for example, polysilicon.

FIG. 2 illustrates porosification system 200, according to an exemplary aspect. Porosification system 200 can be configured to form one or more porous layers in a layer or substrate. In some aspects, porosification system 200 can utilize electrochemical (EC) etching, photoelectrochemical (PEC) etching, or a combination thereof to form one or more porous layers. Although porosification system 200 is shown in FIG. 2 as a stand-alone apparatus and/or system, aspects of this disclosure can be used with other apparatuses, systems, and/or methods.

As shown in FIG. 2, porosification system 200 can include illumination source 210, bath 220, and current source 230. In some aspects, a portion of a layer or substrate (e.g., in-plane or out-of-plane) can be exposed to an electrolyte current such that the portion is etched and a porous region remains. In some aspects, a porosity of the porous region can be controlled by adjusting electrolyte concentration, electrolyte current density, electrolyte current fluid velocity, porosification time, temperature, material doping, illumination power, and/or illumination wavelength. In some aspects, a thickness of the porous region can be controlled by adjusting a porosification (etching) time.

Illumination source 210 is configured to supplement EC etching of a layer or substrate (e.g., substrate 226) in bath 220 with PEC etching to form a porous region in the layer or substrate. PEC etching is dopant and bandgap selective and creates holes at the surface of the layer or substrate. Illumination source 210 can include a UV source (e.g., mercury lamp, arc lamp, etc.) and generate PEC illumination 212 over a portion or all of the layer or substrate. In some aspects, illumination source 210 can be a pulsed light source or include a mechanical modulator (e.g., chopper), an acousto-optical modulator (AOM), or an electro-optical modulator (EOM) to generate pulsed illumination having a particular frequency. In some aspects, illumination source 210 can have a power of about 1 mW to 10 W. In some aspects, illumination source 210 can include an optical filter to apply a particular wavelength(s) to the layer or substrate. In some aspects, illumination source 210 can be omitted for pure EC etching.

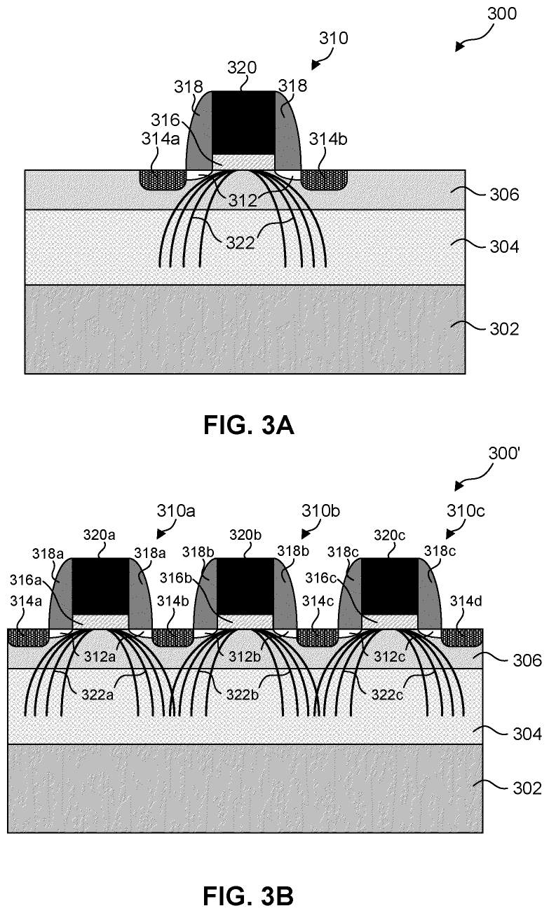

Bath 220 is configured to provide EC etching (e.g., chemical etch) of a layer or substrate (e.g., substrate 226) to form a porous region in the layer or substrate. Bath 220 can include electrolyte 222, electrode 224, and substrate 226 (e.g., substrate 302 shown in FIGS. 3A and 3B). In some aspects, electrolyte 222 can include any material (e.g., acid, alkali, oxidizer, salt, etc.) to facilitate EC etching of substrate 226. For example, electrolyte 222 can include hydrofluoric (HF) acid, buffered HF (5:2), hydrochloric (HCl) acid, hydrobromic (HBr) acid, sulfuric acid (H₂SO₄), nitric acid (HNO₃), oxalic acid (C₂H₂O₄), sodium hydroxide (NaOH), potassium hydroxide (KOH), hydrogen peroxide (H₂O₂), or any other suitable acid, alkali, salt, or oxidizer. Electrode 224 can include any suitable conductor (e.g., metal, copper (Cu), aluminum (Al), platinum (Pt), etc.). In some aspects, bath 220 can maintain a temperature of about 20° C. to about 60° C. In some aspects, substrate 226 can include substrate 302 or a portion (e.g., upper surface) of substrate 302 shown in FIGS. 3A and 3B. In some aspects, substrate 226 can be coupled to a holder such that one side of substrate 226 (e.g., frontside) is exposed to electrolyte 222 during EC etching while the opposite side of the substrate 226 (e.g., backside) is sealed and not exposed to electrolyte 222 during EC etching.

Current source 230 is configured to provide EC etching (e.g., current etch) of a layer or substrate (e.g., substrate 226) to form a porous region in the layer or substrate. Current source 230 can include cathode 232 and anode 234. When combined, current source 230 and bath 220 form an electrolyte current. In some aspects, as shown in FIG. 2, cathode 232 can be connected to electrode 224 and anode 234 can be connected to substrate 226 to complete the circuit. When current is applied, substrate 226 is etched (e.g., porosified), with or without illumination source 210, and electron flow is away from substrate 226 towards electrode 224. Electrons resonate at pore tips in substrate 226 and porosity extends through substrate 226. In some aspects, the electrolyte current density is about 1 mA/cm2 to about 350 mA/cm2. For example, the electrolyte current density can be about 10 mA/cm2 to about 100 mA/cm2. In some aspects, the lattice parameter of the starting material (e.g., substrate 226) remains relatively unchanged following the porosification process. In some aspects, a porosification rate in substrate 226 can be about 1 nm/min to about 25 μm/min. For example, the porosification rate can be about 0.1 μm/min to about 5 μm/min.

In some aspects, porosification system 200 can perform a porosification process (e.g., EC etch) on substrate 226 by exposing a portion of substrate 226 (e.g., frontside) to electrolyte 222 (e.g., buffered HF) and applying (passing) an electrolyzing current (e.g., in a range of 5 mA/cm² to 50 mA/cm²) through substrate 226 from cathode 232 and anode 234 for a specified time (e.g., for 10 seconds to 15 minutes). In some aspects, the porosification process can be carried out in a constant voltage mode (e.g., DC bias of about 5 V to about 25 V) and controlled by monitoring an etching current signal. In some aspects, the porosification process can be carried out in a constant current mode (e.g., DC current of about 5 A to about 25 A) and controlled by monitoring an etching current signal. In some aspects, the porosification process can include oxidation of substrate 226 by localized injection of holes upon application of a positive anodic bias (e.g., anode 234), and localized dissolution of such oxide layer in electrolyte 222 resulting in a porous layer (e.g., porous layer 304 shown in FIGS. 3A and 3B). In some aspects, the porosification process ends when the etching current signal drops to a base line level, indicating that all of the exposed portions of substrate 226 have been porosified and converted into a porous layer (e.g., porous layer 304 shown in FIGS. 3A and 3B).

In some aspects, substrate 226 can comprise any suitable substrate having a predetermined crystallographic orientation, including but not limited to silicon, germanium, and III-V semiconductors. In some aspects, substrate 226 can be doped prior to porosification to adjust a resistivity of substrate 226, for example, to a low-resistivity in a range of about 0.1 Ω·cm to 10 Ω·cm. In some aspects, electrolyte 222 can include a mixture of HF and deionized water, for example, having a ratio of (5:2) and surfactant (1 ml/l). In some aspects, electrolyte 222 can include a mixture of HF and an alcohol (e.g., ethanol), for example, having a ratio of (5:2).

In some aspects, porosification system 200 can form a porous layer (e.g., porous layer 304 shown in FIGS. 3A and 3B) that provides an epitaxy platform for subsequent regrowth of a defect-free, single crystal epilayer (e.g., epilayer 306 shown in FIGS. 3A and 3B). For example, porosification system 200 can form a porous layer (e.g., porous layer 304 shown in FIGS. 3A and 3B) with a low porosity (e.g., about 35%) such that the porous layer is relatively crystalline and long-range crystallinity of the porous layer is not significantly affected by the porosification process.

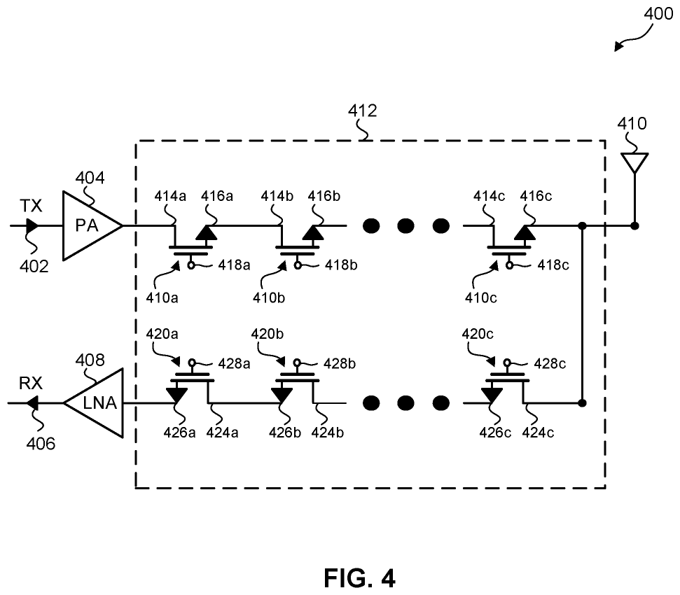

FIGS. 3A and 3B illustrate porous layered structures 300, 300′, according to exemplary aspects. Porous layered structures 300, 300′ can be configured to reduce signal leakage and suppress RF fringing fields (bleeding). In some aspects, porous layered structures 300, 300′ can be utilized in an RF device, for example, RF switch 412 shown in FIG. 4. Although porous layered structures 300, 300′ are shown in FIGS. 3A and 3B as stand-alone apparatuses and/or systems, aspects of this disclosure can be used with other apparatuses, systems, and/or methods.

As shown in FIG. 3A, porous layered structure 300 can include substrate 302 (e.g., silicon), porous layer 304 (e.g., porous silicon), epilayer 306 (e.g., single crystal silicon epilayer), and semiconductor device 310 (e.g., MOSFET) in epilayer 306. In some aspects, porous layered structure 300 with high-resistivity porous layer 304 (e.g., greater than about 5,000 Ω·cm) prevents RF field lines 322 from semiconductor device 310 from penetrating (bleeding) into substrate 302. In some aspects, porous layered structure 300 suppresses harmonic losses, reduces crosstalk, and reduces parasitic surface conduction effects.

In some aspects, substrate 302 can comprise any suitable substrate having a predetermined crystallographic orientation, including but not limited to silicon, germanium, and III-V semiconductors. In some aspects, substrate 302 can be doped prior to porosification to adjust a resistivity of substrate 302, for example, to a low-resistivity in a range of about 0.1 Ω·cm to 10 Ω·cm.

In some aspects, porous layer 304 can be a fully depleted porous layer (i.e., free of charge carriers). In some aspects, porous layer 304 can be a porous silicon layer. For example, porous layer 304 can be formed from a silicon substrate. In some aspects, porous layer 304 can have a resistivity greater than about 5,000 Ω·cm. In some aspects, porous layer 304 can have a thickness greater than about 2 microns. In some aspects, porous layer 304 can have a porosity of about 20% to 80%. In some aspects, porous layer 304 can have a porosity of about 35% to 65%. In some aspects, pores in porous layer 304 can be mesoporous (e.g., 2 nm to 50 nm pore size).

In some aspects, epilayer 306 can be a defect-free, single crystal epilayer formed directly atop porous layer 304. In some aspects, epilayer 306 can comprise any suitable epilayer having a predetermined crystallographic orientation, including but not limited to silicon, germanium, and III-V semiconductors. In some aspects, epilayer 306 can have the same crystallographic orientation as substrate 302.

Semiconductor device 310 can include lightly doped regions 312, source/drain junctions 314a, 314b, gate oxide 316, spacers 318, and gate 320. Lightly doped regions 312 can be implanted with a dopant of a different type (e.g., n-type) than the corresponding epilayer 306 (e.g., p-type). Source/drain junctions 314a, 314b can be implanted with a dopant of the same type as adjacent lightly doped regions 312, but having a higher concentration than lightly doped regions 312. Gate oxide 316 can comprise an electrical insulator, for example, SiO₂. Spacers 318 can comprise an electrical insulator, for example, SiN. Gate 320 can comprise an electrical conductor, for example, polysilicon. In some aspects, semiconductor device 310 can be a transistor (e.g., MOSFET) in a CMOS device, for example, an RF switch (e.g., RF switch 412 shown in FIG. 4).

In some aspects the semiconductor device 310 can be formed directly in or on the porous layer 304 and the epilayer 306 be omitted. The semiconductor device 310 is therefore a passive device such as an inductor or filter.

The aspects of porous layered structure 300 shown in FIG. 3A, for example, and the aspects of porous layered structure 300′ shown in FIG. 3B may be similar. Similar reference numbers are used to indicate features of the aspects of porous layered structure 300 shown in FIG. 3A and the similar features of the aspects of porous layered structure 300′ shown in FIG. 3B.

As shown in FIG. 3B, porous layered structure 300′ can include a plurality of semiconductor devices 310a, 310b, 310c in epilayer 306. In some aspects, semiconductor devices 310a, 310b, 310c can be transistors, for example, MOSFETs. In some aspects, as shown in FIG. 3B, source/drain junction 314b can be shared by semiconductor devices 310a, 310b and source/drain junction 314c can be shared by semiconductor devices 310b, 310c. In some aspects, semiconductor devices 310a, 310b, 310c can be utilized in an RF device, for example, RF switch 412 shown in FIG. 4. For example, semiconductor devices 310a, 310b, 310c can generally correspond to transistors 410a, 410b, 410c (or transistors 420a, 420b, 420c) utilized in RF switch 412 shown in FIG. 4.

In some aspects the semiconductor devices 310a, 310b, 310c can be formed directly in or on the porous layer 304 and the epilayer 306 be omitted. The semiconductor devices 310a, 310b, 310c are therefore a passive device such as an inductor or filter.

FIG. 4 illustrates a circuit diagram of a portion of transceiver 400 with RF switch 412, according to an exemplary aspect. RF switch 412 can be configured to switch transceiver 400 between receive and transmit modes. In some aspects, transceiver 400 can be for a wireless communication device. Although transceiver 400 is shown in FIG. 4 as a stand-alone apparatus and/or system, aspects of this disclosure can be used with other apparatuses, systems, and/or methods.

As shown in FIG. 4, transceiver 400 can include transmit input (TX) 402, power amplifier (PA) 404, receive output (RX) 406, low-noise amplifier (LNA) 408, antenna 410, and RF switch 412. RF switch 412 is situated between PA 404 and antenna 410. PA 404 amplifies RF signals transmitted from transmit input 402. The output of PA 404 is coupled to one end of RF switch 412. Another end of RF switch 412 is coupled to antenna 410. Antenna 410 can transmit amplified RF signals. RF switch 412 is also situated between LNA 408 and antenna 410. Antenna 410 also receives RF signals. Antenna 410 is coupled to one end of RF switch 412. Another end of RF switch 412 is coupled to the input of LNA 408. LNA 408 amplifies RF signals received from RF switch 412. Receive output 406 receives amplified RF signals from LNA 408. In some aspects, RF switch 412 can employ stacked transistors.

RF switch 412 can include two stacks of transistors. The first stack includes transistors 410a, 410b, and 410c. Each transistor 410a, 410b, 410c has a corresponding drain 414a, 414b, 414c, source 416a, 416b, 416c, and gate 418a, 418b, 418c. The second stack includes transistors 420a, 420b, and 420c. Each transistor 420a, 420b, 420c has a corresponding drain 424a, 424b, 424c, source 426a, 426b, 426c, and gate 428a, 428b, 428c. When transistors 410a, 410b, and 410c are in OFF states, and transistors 420a, 420b, and 420c are in ON states, transceiver 400 is in receive mode. When transistors 410a, 410b, and 410c are in ON states, and transistors 420a, 420b, and 420c are in OFF states, transceiver 400 is in transmit mode. In some aspects, RF switch 412 can switch transceiver 400 between two transmit modes corresponding to different frequencies, or between two receive modes corresponding to different frequencies. In some aspects, RF switch 412 can be utilized in a semiconductor structure that reduces signal leakage.

### Exemplary Porous Layered Structures

As discussed above, at device operating temperatures (e.g., at least 200° C.), heat can be transferred into the high-resistivity SOI wafer, thereby creating thermally generated charge carriers that cause thermal donor effects, for example, resulting in decreased resistivity, increased harmonic losses, etc. The amount of thermally generated charge carriers is exponentially dependent upon the negative of the bandgap of the material, for example, bulk silicon (e.g., bandgap of 1.1 eV). The amount of thermally generated charge carriers is proportional to the intrinsic carrier concentration (Nᵢ) of a semiconductor: Nᵢ=\sqrt{N_{c}Nᵥe}^{(-E}^{_{g}}^{/2k}^{_{B}}^{t)}, where N_{c} is the carrier density in the conduction band, Nᵥ is the carrier density in the valence band, E_{g} is the bandgap, k_{B} is Boltzmann's constant, and T is the temperature. Thus, the higher the bandgap of the material (e.g., 1.9 eV for porous silicon), the lower the number of thermally generated carriers at a particular operating temperature (e.g., about 2×10¹² cm⁻³ for porous silicon at 200° C.), and, conversely, the lower the bandgap of the material (e.g., 1.1 eV for bulk silicon), the higher the number of thermally generated charge carriers at a particular operating temperature (e.g., about 1×10¹⁴ cm⁻³ for bulk silicon at 200° C.).

Aspects of porous layer apparatuses, systems, and methods as discussed below can simultaneously decrease thermal donor effects (e.g., decreased resistivity, harmonic losses, etc.), maintain high resistivity of the porous layer (e.g., greater than 5,000 Ω·cm), decrease harmonic losses at device operating temperatures (e.g., at least 200° C.), increase manufacturing efficiency, and increase device performance.

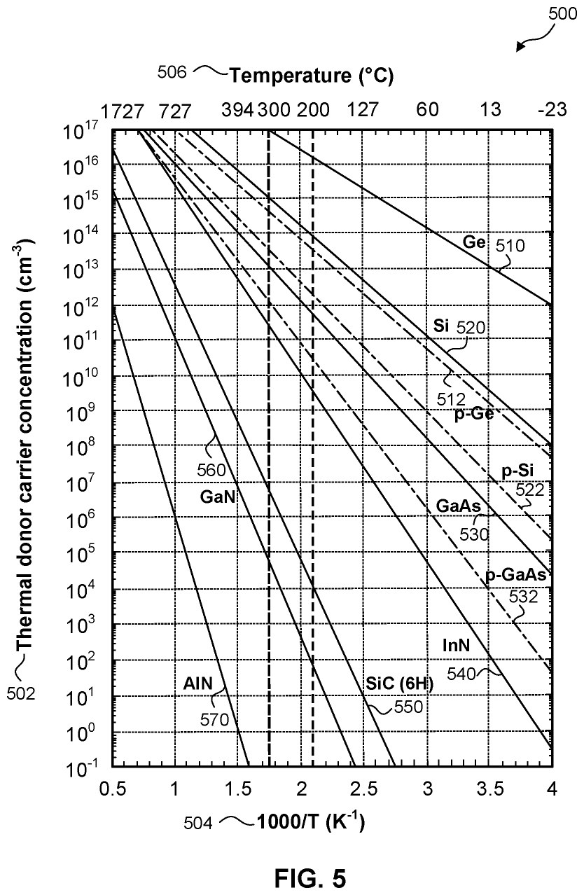

FIG. 5 shows a plot 500 of thermal donor carrier concentrations 502 as a function of temperature 504, 506 for various materials, according to an exemplary aspect. Although plot 500 is shown in FIG. 5 as a stand-alone apparatus and/or system, aspects of this disclosure can be used with other apparatuses, systems, and/or methods, for example, tuned porous layer 304′, porous layered structure 300″, porous layered structure 300′″, manufacturing diagram 800, manufacturing diagram 900, and/or flow diagram 1000.

As shown in FIG. 5, thermal donor carrier concentrations 502 are exponentially dependent upon the temperature 504, 506 and a bandgap of respective materials, including but not limited to, Ge 510, porous Ge (p-Ge) 512, Si 520, porous Si (p-Si) 522, GaAs 530, porous GaAs (p-GaAs) 532, InN 540, SiC (6H) 550, GaN 560, and AlN 570. In some aspects, a bandgap of a material can correspond to a thermal donor carrier concentration 502 at a particular operating temperature 504, 506, for example, as shown below in Table I, for an operating temperature of 200° C.

TABLE I
Thermal Donor Carrier Concentrations at 200° C.

| | | Thermal Donor |
|---|---|---|
| Material | Bandgap (eV) | Carrier Concentration (cm⁻³) |
| Ge | 0.67 | 1 × 10¹⁶ |
| Porous Ge | 2.2 to 3.1 | 1.6 × 10¹⁵ to 4.8 × 10¹³ |
| Si | 1.1 | 1 × 10¹⁴ |
| Porous Si | 1.7 to 2.2 | 4.5 × 10¹³ to 1.5 × 10¹² |
| GaAs | 1.42 | 6 × 10¹¹ |
| Porous GaAs | 1.47 to 2.3 | 5 × 10¹¹ to 1 × 10¹⁰ |
| InN | 0.7 | 4 × 10⁹ |
| SiC (6H) | 3.02 | 1 × 10⁴ |
| GaN | 3.3 | 6 × 10¹ |
| AIN | 6.2 | 1 × 10⁻⁵ |

In some aspects, porous materials can have a variable (tunable) bandgap and, thus, a variable thermal donor carrier concentration 502, based on a porosity of the porous material (e.g., as a function of an electrolyte concentration, an electrolyte current density, an electrolyte current fluid velocity, an anodization time, a temperature, a material doping, or a combination thereof during porosification of a material to form the porous layer). For example, as shown in Table I, porous Ge 512 can have a bandgap of about 2.2 eV to about 3.1 eV (e.g., porosity of about 20% to about 80%) corresponding to a thermal donor carrier concentration 502 of about 1.6×10¹⁵ cm⁻³ to about 4.8×10¹³ cm⁻³, porous Si 522 can have a bandgap of about 1.7 eV to about 2.2 eV (e.g., porosity of about 20% to about 80%) corresponding to a thermal donor carrier concentration 502 of about 4.5×10¹³ cm⁻³ to about 1.5×10¹² cm⁻³, and porous GaAs 532 can have a bandgap of about 1.47 eV to about 2.3 eV (e.g., porosity of about 20% to about 80%) corresponding to a thermal donor carrier concentration 502 of about 5×10¹¹ cm⁻³ to about 1×10¹⁰ cm⁻³, respectively.

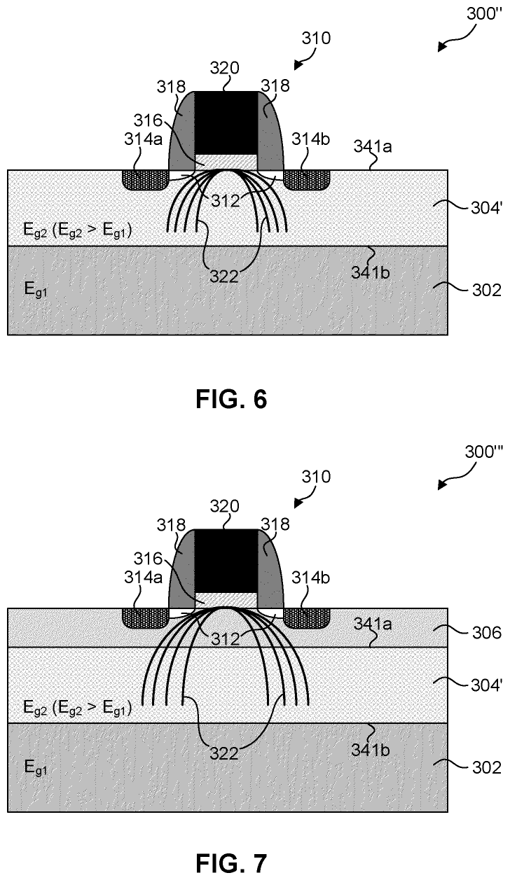

In some aspects, a bandgap ratio of a porous material bandgap (e.g., porous Si 522) to a corresponding substrate material bandgap (e.g., bulk Si 520), for example, from which the porous material is formed, can be determined, for example, as shown below in Table II. In some aspects, the bandgap ratio (e.g., bandgap ratio of at least 1.6) can be configured to decrease thermal donor effects in a porous layered structure (e.g., porous layered structures 300″, 300′″ shown in FIGS. 6 and 7).

TABLE II
Bandgap Ratios

| Material | Bandgap (eV) | Bandgap Ratio |
|---|---|---|
| Ge | 0.67 | 3.28 to 4.62 |
| Porous Ge | 2.2 to 3.1 | |
| Si | 1.1 | 1.54 to 2 |
| Porous Si | 1.7 to 2.2 | |
| GaAs | 1.42 | 1.04 to 1.62 |
| Porous GaAs | 1.47 to 2.3 | |

In some aspects, a thermal donor carrier concentration ratio of a thermal donor carrier concentration 502 of a substrate material (e.g., bulk Si 520) to a thermal donor carrier concentration 502 of a porous material (e.g., porous Si 522), for example, formed from the substrate material (e.g., bulk Si 520), at a particular operating temperature 504, 506 can be determined, for example, as shown below in Table III, for an operating temperature of 200° C. In some aspects, the thermal donor carrier concentration ratio (e.g., thermal donor carrier concentration of at least 50) can be configured to decrease thermal donor effects in a porous layered structure (e.g., porous layered structures 300″, 300′″ shown in FIGS. 6 and 7).

TABLE III
Thermal Donor Concentration Ratios at 200° C.

| | Thermal Donor Carrier | Thermal Donor Carrier |
|---|---|---|
| Material | Concentration (cm⁻³) | Concentration Ratio |
| Ge | 1 × 10¹⁶ | 6.25 to 208 |
| Porous Ge | 1.6 × 10¹⁵ to 4.8 × 10¹³ | |
| Si | 1 × 10¹⁴ | 2.2 to 66.7 |
| Porous Si | 4.5 × 10¹³ to 1.5 × 10¹² | |
| GaAs | 6 × 10¹¹ | 1.2 to 60 |
| Porous GaAs | 5 × 10¹¹ to 1 × 10¹⁰ | |

FIG. 6 illustrates porous layered structure 300″ with tuned porous layer 304′, according to an exemplary aspect. Porous layered structure 300″ can be configured to decrease thermal donor effects (e.g., decreased resistivity, harmonic losses, etc.). Porous layered structure 300″ can be further configured to decrease harmonic losses in semiconductor device 310, for example, at device operating temperatures (e.g., at least 200° C.). Porous layered structure 300″ can be further configured to maintain high resistivity of tuned porous layer 304′ (e.g., greater than 5,000 Ω·cm). Although porous layered structure 300″ is shown in FIG. 6 as a stand-alone apparatus and/or system, aspects of this disclosure can be used with other apparatuses, systems, and/or methods, for example, plot 500, porous layered structure 300′″, manufacturing diagram 800, manufacturing diagram 900, and/or flow diagram 1000.

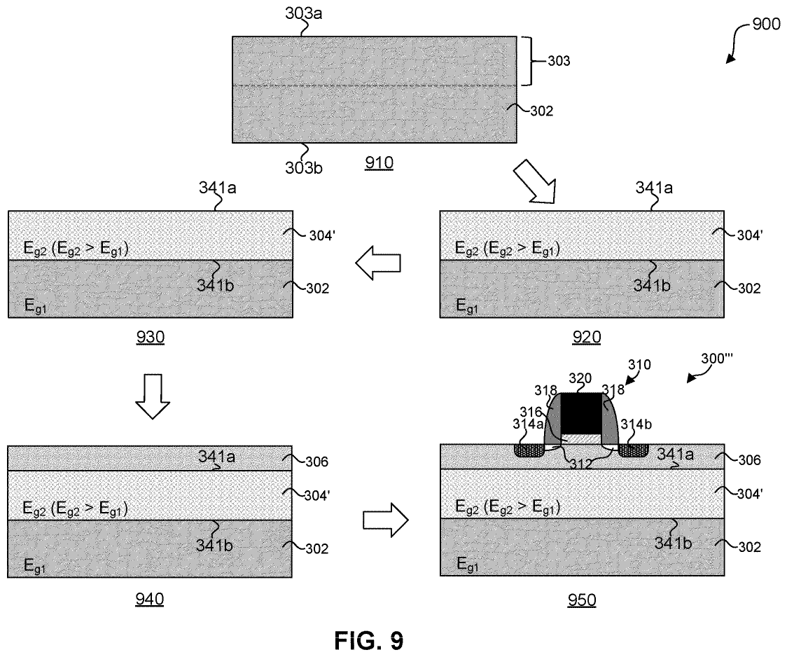

The aspects of porous layered structure 300 shown in FIGS. 3A and 9, for example, and the aspects of porous layered structure 300″ shown in FIG. 6 may be similar. Similar reference numbers are used to indicate features of the aspects of porous layered structure 300 shown in FIGS. 3A and 9 and the similar features of the aspects of porous layered structure 300″ shown in FIG. 6.

As shown in FIG. 6, porous layered structure 300″ can include substrate 302 with first bandgap (E_{g1}) and tuned porous layer 304′ with second bandgap (E_{g2}), where second bandgap (E_{g2}) is greater than first bandgap (E_{g1}). In some aspects, substrate 302 can include a Group IV semiconductor, a Group III-V semiconductor, or a combination thereof. For example, substrate 302 can include Si (e.g., Si 520), Ge (e.g., Ge 510), GaAs (e.g., GaAs 530), InN (e.g., InN 540), InP, SiC (e.g., SiC (6H) 550), GaN (e.g., GaN 560), or AlN (e.g., AlN 570). In some aspects, tuned porous layer 304′ can include a porous Group IV semiconductor, a porous Group III-V semiconductor, or a combination thereof. For example, tuned porous layer 304′ can include porous Si (e.g., p-Si 522), porous Ge (e.g., p-Ge 512), porous GaAs (e.g., p-GaAs 532), porous InN, porous InP, porous SiC, porous GaN, or porous AlN.

In some aspects, second bandgap (E_{g2}) of tuned porous layer 304′ can be based on a porosity of tuned porous layer 304′. For example, second bandgap (E_{g2}) can be in a range between about 1.7 eV to about 2.2 eV (e.g., for porous Si 522) based on a porosity range between about 20% to about 80%, respectively. In some aspects, second bandgap (E_{g2}) of tuned porous layer 304′ can be tuned to a specific bandgap value (e.g., 1.9 eV for porous Si 522) based on the porosity of tuned porous layer 304′, for example, by adjusting an electrolyte concentration, an electrolyte current density, an electrolyte current fluid velocity, an anodization time, a temperature, a material doping, or a combination thereof during porosification of substrate 302 (e.g., Si 520) to form tuned porous layer 304′.

In some aspects, tuned porous layer 304′ can include any porous material having a second bandgap (E_{g2}) greater than a first bandgap (E_{g1}) of substrate 302. For example, tuned porous layer 304′ can include porous Ge 512 with second bandgap (E_{g2}) being in a range of about 2.2 eV to 3.1 eV (e.g., about 2.4 eV) and substrate 302 can include Ge 510 with first bandgap (E_{g1}) equal to about 0.67 eV. For example, tuned porous layer 304′ can include porous Si 522 with second bandgap (E_{g2}) being in a range of about 1.7 eV to 2.2 eV (e.g., about 1.9 eV) and substrate 302 can include Si 520 with first bandgap (E_{g1}) equal to about 1.1 eV. For example, tuned porous layer 304′ can include porous GaAs 532 with second bandgap (E_{g2}) being in a range of about 1.47 eV to 2.3 eV (e.g., about 2.2 eV) and substrate 302 can include GaAs 530 with first bandgap (E_{g1}) equal to about 1.42 eV.

In some aspects, a bandgap ratio (E_{g2}/E_{g1}) of second bandgap (E_{g2}) to first bandgap (E_{g1}) can be at least 1.6. For example, first bandgap (E_{g1}) can be about 1.1 eV (e.g., Si) and second bandgap (E_{g2}) can be about 1.78 eV (e.g., porous Si), having a bandgap ratio (E_{g2}/E_{g1}) of about 1.62. For example, first bandgap (E_{g1}) can be about 1.42 eV (e.g., GaAs) and second bandgap (E_{g2}) can be about 2.3 eV (e.g., porous GaAs), having a bandgap ratio (E_{g2}/E_{g1}) of about 1.62.

In some aspects, the bandgap ratio (E_{g2}/E_{g1}) can be at least 1.9. For example, first bandgap (E_{g1}) can be about 1.1 eV (e.g., Si) and second bandgap (E_{g2}) can be about 2.1 eV (e.g., porous Si), having a bandgap ratio (E_{g2}/E_{g1}) of about 1.91. In some aspects, the bandgap ratio (E_{g2}/E_{g1}) can be at least 2.5. For example, first bandgap (E_{g1}) can be about 0.67 eV (e.g., Ge) and second bandgap (E_{g2}) can be about 2.2 eV (e.g., porous Ge), having a bandgap ratio (E_{g2}/E_{g1}) of about 3.28. In some aspects, the bandgap ratio (E_{g2}/E_{g1}) can be at least 4. For example, first bandgap (E_{g1}) can be about 0.67 eV (e.g., Ge) and second bandgap (E_{g2}) can be about 2.8 eV (e.g., porous Ge), having a bandgap ratio (E_{g2}/E_{g1}) of about 4.18.

In some aspects, tuned porous layer 304′ can have a thermal donor carrier concentration of no greater than about 1×10¹³ cm⁻³ at an operating temperature of at least 200° C. For example, as shown in FIG. 5, porous Si 522 (e.g., second bandgap (E_{g2}) of about 1.9 eV) can have a thermal donor carrier concentration 502 of about 2×10¹² cm⁻³ at an operating temperature of about 200° C. In some aspects, tuned porous layer 304′ can have a thermal donor carrier concentration of no greater than about 1×10¹² cm⁻³ at an operating temperature of at least 200° C. For example, as shown in FIG. 5, porous GaAs 532 (e.g., second bandgap (E_{g2}) of about 1.5 eV) can have a thermal donor carrier concentration 502 of about 2.4×10¹⁰ cm⁻³ at an operating temperature of about 200° C. In some aspects, tuned porous layer 304′ can have a thermal donor carrier concentration of no greater than about 1×10¹¹ cm⁻³ at an operating temperature of at least 200° C. For example, porous GaAs (e.g., second bandgap (E_{g2}) of about 1.8 eV) can have a thermal donor carrier concentration of about 1.8×10¹⁰ cm⁻³ at an operating temperature of about 200° C. In some aspects, tuned porous layer 304′ can have a thermal donor carrier concentration of no greater than about 1×10¹⁰ cm⁻³ at an operating temperature of at least 200° C. For example, porous GaAs (e.g., second bandgap (E_{g2}) of about 2.3 eV) can have a thermal donor carrier concentration of about 1×10¹⁰ cm⁻³ at an operating temperature of about 200° C.

In some aspects, a thermal donor carrier concentration ratio of a thermal donor carrier concentration of substrate 302 to a thermal donor carrier concentration of tuned porous layer 304′ can be at least 50. For example, as shown in FIG. 5, substrate 302 thermal donor carrier concentration 502 can be about 1×10¹⁴ cm⁻³ (e.g., Si 520 at about 200° C.) and tuned porous layer 304′ thermal donor carrier concentration 502 can be about 2×10¹² cm⁻³ (e.g., porous Si 522 at about 200° C.), having a thermal donor carrier concentration ratio of about 50.

In some aspects, the thermal donor carrier concentration ratio can be at least 100. For example, substrate 302 thermal donor carrier concentration 502 can be about 1×10¹⁶ cm⁻³ (e.g., Ge 510 at about 200° C.) and tuned porous layer 304′ thermal donor carrier concentration 502 can be about 9.1×10¹³ cm⁻³ (e.g., porous Ge at about 200° C.), having a thermal donor carrier concentration ratio of about 110.

In some aspects, the thermal donor carrier concentration ratio can be at least 200. For example, substrate 302 thermal donor carrier concentration 502 can be about 1×10¹⁶ cm⁻³ (e.g., Ge 510 at about 200° C.) and tuned porous layer 304′ thermal donor carrier concentration 502 can be about 4.8×10¹³ cm⁻³ (e.g., porous Ge at about 200° C.), having a thermal donor carrier concentration ratio of about 208.

In some aspects, tuned porous layer 304′ can be elementally identical to substrate 302. For example, substrate 302 can be bulk Si (e.g., Si 520) and tuned porous layer 304′ can be porous Si (e.g., porous Si 522). For example, substrate 302 can be bulk Ge (e.g., Ge 510) and tuned porous layer 304′ can be porous Ge (e.g., porous Ge 512). For example, substrate 302 can be bulk GaAs (e.g., GaAs 530) and tuned porous layer 304′ can be porous GaAs (e.g., porous GaAs 532).

In some aspects, tuned porous layer 304′ can be a fully depleted porous layer having no free charge carriers. In some aspects, first resistivity of substrate 302 can be between about 0.01 Ω·cm and 10 Ω·cm. In some aspects, second resistivity of tuned porous layer 304′ can be at least 5,000 Ω·cm. In some aspects, tuned porous layer 304′ can have a thickness of at least 2 μm. For example, tuned porous layer 304′ can have a thickness of about 5 μm.

In some aspects, as shown in FIG. 6, porous layered structure 300″ can include semiconductor device 310 in tuned porous layer 304′. In some aspects, porous layered structure 300″ can include a semiconductor device on tuned porous layer 304′. In some aspects, semiconductor device 310 in or on tuned porous layer 304′ can include a passive device (e.g., an inductor, a filter, etc.). In some aspects, semiconductor device 310 in or on tuned porous layer 304′ can include an RF device (e.g., an RF inductor, an RF filter, etc.). In some aspects, porous layered structure 300″ can include an epitaxial layer grown directly over tuned porous layer 304′. For example, as shown in FIG. 7, porous layered structure 300′″ can include epilayer 306 over tuned porous layer 304′. In some aspects, as shown in FIG. 7, porous layered structure 300′″ can include semiconductor device 310 in epilayer 306. In some aspects, the bandgap ratio (E_{g2}/E_{g1}) can be configured to decrease a thermal donor carrier concentration 502 of tuned porous layer 304′ thereby decreasing harmonic losses in semiconductor device 310.

FIG. 7 illustrates porous layered structure 300′″ with tuned porous layer 304′ and epilayer 306, according to an exemplary aspect. Porous layered structure 300′″ can be configured to decrease thermal donor effects (e.g., decreased resistivity, harmonic losses, etc.). Porous layered structure 300′″ can be further configured to decrease harmonic losses in semiconductor device 310, for example, at device operating temperatures (e.g., at least 200° C.). Porous layered structure 300′″ can be further configured to maintain high resistivity of tuned porous layer 304′ (e.g., greater than 5,000 Ω·cm). Although porous layered structure 300′″ is shown in FIG. 7 as a stand-alone apparatus and/or system, aspects of this disclosure can be used with other apparatuses, systems, and/or methods, for example, plot 500, porous layered structure 300″, manufacturing diagram 800, manufacturing diagram 900, and/or flow diagram 1000.

The aspects of porous layered structure 300″ shown in FIG. 6, for example, and the aspects of porous layered structure 300′″ shown in FIG. 7 may be similar. Similar reference numbers are used to indicate features of the aspects of porous layered structure 300″ shown in FIG. 6 and the similar features of the aspects of porous layered structure 300′″ shown in FIG. 7.

### Exemplary Manufacturing Diagrams

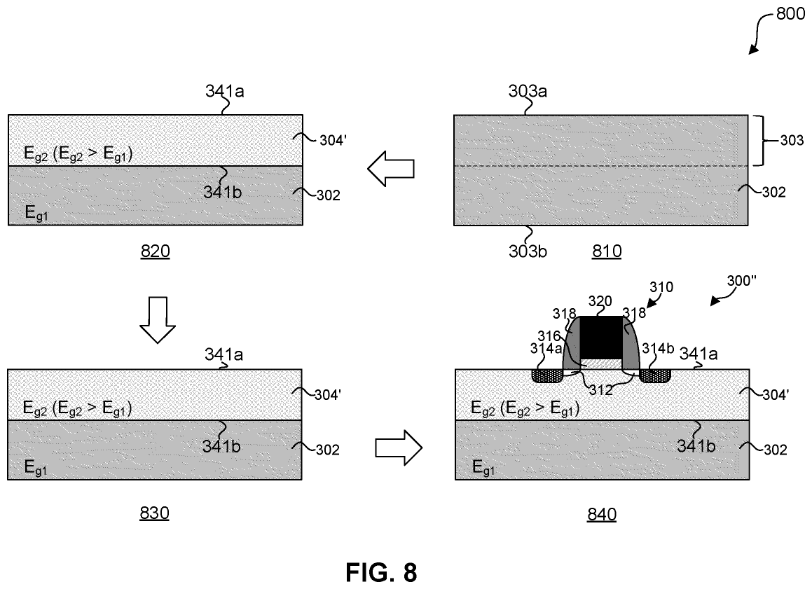

FIG. 8 illustrates manufacturing diagram 800 for forming porous layered structure 300″, according to an exemplary aspect. It is to be appreciated that not all steps in FIG. 8 are needed to perform the disclosure provided herein. Further, some of the steps can be performed simultaneously, sequentially, and/or in a different order than shown in FIG. 8. Manufacturing diagram 800 shall be described with reference for FIGS. 5 and 6. However, manufacturing diagram 800 is not limited to those example aspects.

As shown in FIG. 8, manufacturing diagram 800 is configured to form porous layered structure 300″ shown in FIG. 6. In step 810, a substrate 302 having a frontside 303a, a backside 303b, and a first bandgap (E_{g1}) is selected. In some aspects, substrate 302 can include any suitable substrate having a predetermined crystallographic orientation, including but not limited to silicon, germanium, and III-V semiconductors.

In step 820, a portion 303 of substrate 302 is porosified from frontside 303a towards backside 303b to form tuned porous layer 304′ having a second bandgap (E_{g2}) greater than first bandgap (E_{g1}) of substrate 302. In some aspects, the second bandgap (E_{g2}) of tuned porous layer 304′ can be based on an electrolyte concentration, an electrolyte current density, an electrolyte current fluid velocity, an anodization time, a temperature, a material doping, or a combination thereof utilized during the porosification of substrate 302 to form tuned porous layer 304′. In some aspects, the second bandgap (E_{g2}) of tuned porous layer 304′ can be tuned to a specific bandgap value (e.g., porous Ge 512, porous Si 522, porous GaAs 532) based on one or more adjustable parameters during porosification.

In some aspects, shown as optional step 830, manufacturing diagram 800 can include annealing tuned porous layer 304′ after step 820 but prior to step 840. For example, tuned porous layer 304′ can be annealed at a temperature between about 300° C. to about 500° C. For example, tuned porous layer 304′ can be annealed in an oxidation environment (e.g., oxygen, air, water vapor, etc.). In some aspects, after step 820 or optional step 830 but prior to step 840, tuned porous layer 304′ can undergo a touch polish to remove an upper surface layer (e.g., frontside 341a). For example, frontside 341a of tuned porous layer 304′ can be polished by a CMP or planarization process. In some aspects, after step 820 or optional step 830 but prior to step 840, tuned porous layer 304′ can undergo a plasma surface etch to remove an upper surface layer (e.g., frontside 341a). For example, frontside 341a of tuned porous layer 304′ can be etched by a plasma etcher. In some aspects, manufacturing diagram 800 can further include exposing tuned porous layer 304′ to an acid solution (e.g., HF) after step 820 but prior to step 830 or after step 820 but prior to step 840.

In step 840, a semiconductor device 310 is formed in tuned porous layer 304′ to form porous layered structure 300″. In some aspects, semiconductor device 310 can be a transistor (e.g., MOSFET) in a CMOS device, for example, an RF switch (e.g., RF switch 412 shown in FIG. 4). In some aspects, semiconductor device 310 can include a passive device (e.g., an inductor, a filter, etc.). In some aspects, semiconductor device 310 can include an RF device (e.g., an RF inductor, an RF filter, etc.). In some aspects, porous layered structure 300″ can omit semiconductor device 310 in tuned porous layer 304′, for example, as shown in step 820 of FIG. 8.

The aspects of manufacturing diagram 800 shown in FIG. 8, for example, and the aspects of manufacturing diagram 900 shown in FIG. 9 may be similar. Similar reference numbers are used to indicate features of the aspects of manufacturing diagram 800 shown in FIG. 8 and the similar features of the aspects of manufacturing diagram 900 shown in FIG. 9.

FIG. 9 illustrates manufacturing diagram 900 for forming porous layered structure 300′″, according to an exemplary aspect. It is to be appreciated that not all steps in FIG. 9 are needed to perform the disclosure provided herein. Further, some of the steps can be performed simultaneously, sequentially, and/or in a different order than shown in FIG. 9. Manufacturing diagram 900 shall be described with reference for FIGS. 5 and 7. However, manufacturing diagram 900 is not limited to those example aspects.

As shown in FIG. 9, manufacturing diagram 900 is configured to form porous layered structure 300′″ shown in FIG. 7. In step 910, a substrate 302 having a frontside 303a, a backside 303b, and a first bandgap (E_{g1}) is selected. In some aspects, substrate 302 can include any suitable substrate having a predetermined crystallographic orientation, including but not limited to silicon, germanium, and III-V semiconductors.

In step 920, a portion 303 of substrate 302 is porosified from frontside 303a towards backside 303b to form tuned porous layer 304′ having a second bandgap (E_{g2}) greater than first bandgap (E_{g1}) of substrate 302. In some aspects, the second bandgap (E_{g2}) of tuned porous layer 304′ can be based on an electrolyte concentration, an electrolyte current density, an electrolyte current fluid velocity, an anodization time, a temperature, a material doping, or a combination thereof utilized during the porosification of substrate 302 to form tuned porous layer 304′. In some aspects, the second bandgap (E_{g2}) of tuned porous layer 304′ can be tuned to a specific bandgap value (e.g., porous Ge 512, porous Si 522, porous GaAs 532) based on one or more adjustable parameters during porosification.

In some aspects, shown as optional step 930, manufacturing diagram 900 can include annealing tuned porous layer 304′ after step 920 but prior to step 940. For example, tuned porous layer 304′ can be annealed at a temperature between about 300° C. to about 500° C. For example, tuned porous layer 304′ can be annealed in an oxidation environment (e.g., oxygen, air, water vapor, etc.). In some aspects, after step 920 or optional step 930 but prior to step 940, tuned porous layer 304′ can undergo a touch polish to remove an upper surface layer (e.g., frontside 341a). For example, frontside 341a of tuned porous layer 304′ can be polished by a CMP or planarization process. In some aspects, after step 920 or optional step 930 but prior to step 940, tuned porous layer 304′ can undergo a plasma surface etch to remove an upper surface layer (e.g., frontside 341a). For example, frontside 341a of tuned porous layer 304′ can be etched by a plasma etcher. In some aspects, manufacturing diagram 900 can further include exposing tuned porous layer 304′ to an acid solution (e.g., HF) after step 920 or optional step 930 but prior to step 940.

In step 940, an epilayer 306 is grown over tuned porous layer 304′ (e.g., on frontside 341a). In some aspects, epilayer 306 can include any suitable epilayer having a predetermined crystallographic orientation, including but not limited to silicon, germanium, and III-V semiconductors. In some aspects, epilayer 306 can be a defect-free, single crystal epilayer formed directly atop tuned porous layer 304′.

In step 950, a semiconductor device 310 is formed in epilayer 306 to form porous layered structure 300′″. In some aspects, semiconductor device 310 can be a transistor (e.g., MOSFET) in a CMOS device, for example, an RF switch (e.g., RF switch 412 shown in FIG. 4). In some aspects, porous layered structure 300′″ can omit semiconductor device 310 in epilayer 306, for example, as shown in step 940 of FIG. 9. In some aspects, porous layered structure 300′″ can omit epilayer 306 over tuned porous layer 304′, for example, as shown in step 920 of FIG. 9.

### Exemplary Flow Diagram

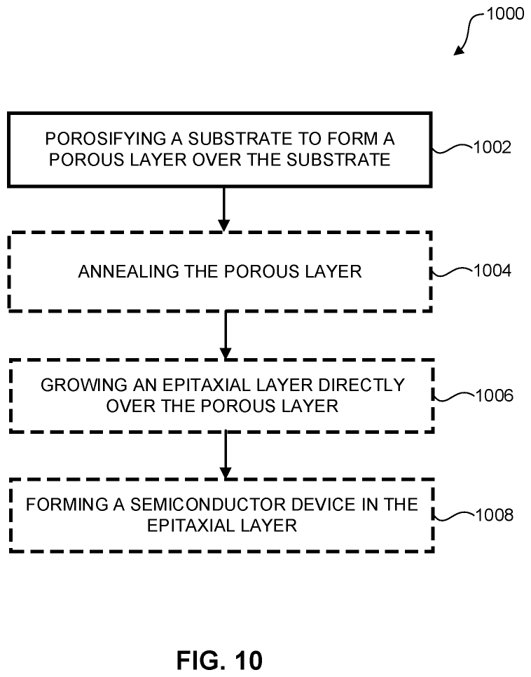

FIG. 10 illustrates flow diagram 1000 to describe the processes of forming porous layered structures 300″, 300′″, according to exemplary aspects. It is to be appreciated that not all steps in FIG. 10 are needed to perform the disclosure provided herein. Further, some of the steps can be performed simultaneously, sequentially, and/or in a different order than shown in FIG. 10. Flow diagram 1000 shall be described with reference to FIGS. 5-9. However, flow diagram 1000 is not limited to those example aspects.

As shown in FIG. 10, flow diagram 1000 describes the processes to form porous layered structure 300″ shown in FIG. 6 and porous layered structure 300′″ shown in FIG. 7. In step 1002, as shown in the example of FIGS. 8 and 9, a portion 303 of substrate 302 is porosified from frontside 303a towards backside 303b to form tuned porous layer 304′ having a second bandgap (E_{g2}) greater than first bandgap (E_{g1}) of substrate 302. In some aspects, the second bandgap (E_{g2}) of tuned porous layer 304′ can be based on an electrolyte concentration, an electrolyte current density, an electrolyte current fluid velocity, an anodization time, a temperature, a material doping, or a combination thereof utilized during the porosification of substrate 302 to form tuned porous layer 304′. In some aspects, the second bandgap (E_{g2}) of tuned porous layer 304′ can be tuned to a specific bandgap value (e.g., porous Ge 512, porous Si 522, porous GaAs 532) based on one or more adjustable parameters during porosification. In some aspects, flow diagram 1000 can further include forming a semiconductor device 310 in tuned porous layer 304′ to form porous layered structure 300″, for example, as shown in step 840 of FIG. 8.

In some aspects, shown as optional step 1004, as shown in the example of FIG. 9, flow diagram 1000 can include annealing tuned porous layer 304′ after step 1002 but prior to optional step 1006 or optional step 1008. For example, tuned porous layer 304′ can be annealed at a temperature between about 300° C. to about 500° C. For example, tuned porous layer 304′ can be annealed in an oxidation environment (e.g., oxygen, air, water vapor, etc.). In some aspects, shown as optional step 1006, as shown in the example of FIG. 9, an epilayer 306 is grown over tuned porous layer 304′ (e.g., on frontside 341a). In some aspects, shown as optional step 1008, as shown in the example of FIG. 9, a semiconductor device 310 is formed in epilayer 306 to form porous layered structure 300′″.

It is to be understood that the phraseology or terminology herein is for the purpose of description and not of limitation, such that the terminology or phraseology of the present specification is to be interpreted by those skilled in relevant art(s) in light of the teachings herein.

The following examples are illustrative, but not limiting, of the aspects of this disclosure. Other suitable modifications and adaptations of the variety of conditions and parameters normally encountered in the field, and which would be apparent to those skilled in the relevant art(s), are within the spirit and scope of the disclosure.

While specific aspects have been described above, it will be appreciated that the aspects can be practiced otherwise than as described. The description is not intended to limit the scope of the claims.

The aspects have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects will so fully reveal the general nature of the aspects that others can, by applying knowledge within the skill of the art, readily modify and/or adapt for various applications such specific aspects, without undue experimentation, without departing from the general concept of the aspects. Therefore, such adaptations and modifications are intended to be within the meaning and range of equivalents of the disclosed aspects, based on the teaching and guidance presented herein.

The breadth and scope of the aspects should not be limited by any of the above-described exemplary aspects, but should be defined only in accordance with the following claims and their equivalents.

1. A layered structure comprising:
a substrate having a first resistivity and a first bandgap (E_{g1}); and
a porous layer over the substrate, the porous layer having a second resistivity higher than the substrate and a second bandgap (E_{g2}) higher than the first bandgap (E_{g1}), wherein a bandgap ratio (E_{g2}/E_{g1}) of the second bandgap (E_{g2}) to the first bandgap (E_{g1}) is at least 2.5.

2. The layered structure of claim 1, wherein the porous layer has a thermal donor carrier concentration of no greater than 1×10¹³ cm⁻³ at an operating temperature of at least 100° C., or no greater than 1×10¹² cm⁻³ at an operating temperature of at least 100° C., or no greater than 1×10¹¹ cm⁻³ at an operating temperature of at least 100° C., or no greater than 1×10¹⁰ cm⁻³ at an operating temperature of at least 100° C.

3. The layered structure of claim 1, wherein a thermal donor carrier concentration ratio of a thermal donor carrier concentration of the substrate to a thermal donor carrier concentration of the porous layer is at least 50, or at least 100, or at least 200.

4. The layered structure of claim 1, wherein the porous layer comprises a porous Group IV semiconductor, a porous Group III-V semiconductor, porous silicon (Si), porous germanium (Ge), porous gallium arsenide (GaAs), porous indium nitride (InN), porous indium phosphide (InP), porous silicon carbide (SiC), porous gallium nitride (GaN), porous aluminum nitride (AlN), or a combination thereof, and
wherein the porous layer is elementally identical to the substrate.

5. The layered structure of claim 1, wherein the porous layer is a fully depleted porous layer having no free charge carriers.

6. The layered structure of claim 1, wherein the first resistivity of the substrate is between 0.01 Ω·cm and 10 Ω·cm.

7. The layered structure of claim 1, wherein the second resistivity of the porous layer is at least 5,000 Ω·cm.

8. The layered structure of claim 1, wherein the porous layer has a thickness of at least 2 μm.

9. The layered structure of claim 1, further comprising a semiconductor device in or on the porous layer.

10. The layered structure of claim 1, further comprising an epitaxial layer grown directly over the porous layer.

11. The layered structure of claim 10, further comprising a semiconductor device in the epitaxial layer.

12. A method comprising:
forming a porous layer over a substrate, the porous layer having a second bandgap (E_{g2}) higher than a first bandgap (E_{g1}) of the substrate,
wherein a bandgap ratio (E_{g2}/E_{g1}) of the second bandgap (E_{g2}) to the first bandgap (E_{g1}) is at least 2.5.

13. The method of claim 12, wherein a thermal donor carrier concentration ratio of a thermal donor carrier concentration of the substrate to a thermal donor carrier concentration of the porous layer is at least 50.

14. The method of claim 12, further comprising annealing the porous layer in an oxidation environment.

15. The method of claim 12, wherein forming the porous layer comprises porosifying an upper portion of the substrate.

16. The method of claim 15, wherein the second bandgap (E_{g2}) of the porous layer is based on an electrolyte concentration, an electrolyte current density, an electrolyte current fluid velocity, an anodization time, a temperature, a material doping, or a combination thereof during porosifying.

17. The method of claim 12, further comprising forming a semiconductor device in the porous layer.

18. The method of claim 12, further comprising growing an epitaxial layer directly over the porous layer.

19. The method of claim 18, further comprising polishing or etching a frontside of the porous layer prior to growing the epitaxial layer.

20. The method of claim 19, further comprising forming a semiconductor device in the epitaxial layer.
